(19) United States
(12) Patent Application Publication
(10) Pub. No.: US 2019/0041450 A1
(43) Pub. Date: Feb. 7, 2019

(54) AN INTELLIGENT ASSESSMENT METHOD OF MAIN INSULATION CONDITION OF TRANSFORMER OIL PAPER INSULATION

(71) Applicants: Yandong LV, Shanghai (CN); General Electric Technology GmbH, Baden (CH)

(72) Inventors: Lijun YANG, Shapingba District, Chongqing (CN); RuiJin LIAO, Shapingba District, Chongqing (CN); Gao JUN, Shapingba District, Chongqing (CN); Liu XIAO, Shapingba District, Chongqing (CN); Mamadou Lamine COULIBALY, Massy (FR); Gilbert LUNA, Massy (FR); Yandong LV, Shanghai (CN)

(21) Appl. No.: 15/779,098

(22) PCT Filed: Dec. 1, 2015
(86) PCT No.: PCT/CN2015/096085

§ 371 Date: May 25, 2018

(51) Int. Cl. G01R 31/12; G01R 31/02; H01F 27/32

(52) U.S. Cl. CPC G01R 31/1263; H01F 27/32; G01R 31/027

(57) ABSTRACT

The invention provides an intelligent assessment method of main insulation condition of transformer oil paper insulation, comprising: establishing at least one standard states; for each standard state, performing accelerated thermal aging tests on a plurality of samples to place the samples in the standard state, wherein each of the plurality of samples undergoes the accelerated thermal aging tests for different time periods; extracting time and frequency domain characteristic parameters of each of the plurality of samples; forming a feature vector using the time and frequency domain characteristic parameters of each sample, and forming a knowledge base from feature vectors of all samples; training a classifier by using the feature vectors of the knowledge base; and assessing the main insulation condition by using the trained classifier. The intelligent assessment method of the invention considers insulation geometry, temperature and oil of transformer, and thus is suitable for field assessment of different voltage grades of oil-immersed transformer insulation condition.

### FIELD OF THE INVENTION

The invention refers to insulation aging and lifetime prediction of electrical devices, and particularly refers to an intelligent assessment method of main insulation condition of transformer oil paper insulation.

### BACKGROUND

Physico-chemical parameters and electric parameters are widely used to assess the aging conditions of transformer insulation.

By way of example, physico-chemical characteristics, such as degree of polymerization and mechanical properties (tensile strength), are among the most reliable ones to monitor the aging state of cellulose insulation, but these methods need to open the transformer and take samples from several most typical parts of windings, which are difficult to implement and will possibly damage the insulation in transformers;

Dissolved gas (CO, CO2) in oil and furfural content (2-FAL) can also be used as aging markers to assess the paper insulation condition, but the assessment accuracy will be influenced by oil filtering, degree of degradation of cellulose insulation. In addition, CO and CO2 gases can be also produced due to the aging of oil alone;

Moreover, electric parameters including insulation resistance, polarization index and dielectric dissipation factor have been chosen as the moisture characterization of transformers by the power sector for a long time. Unfortunately, until the last century 90's, there is still no electric diagnosis method with systematic research for transformer insulation aging conditions assessment.

### SUMMARY

Directing to actual application requirement in the art, the invention provides an intelligent assessment method of main insulation condition of transformer oil paper insulation, comprising:

establishing at least one standard states;

for each standard state, performing accelerated thermal aging tests on a plurality of samples to place the samples in the standard state, wherein each of the plurality of samples undergoes the accelerated thermal aging tests for different time periods;

extracting time and frequency domain characteristic parameters of each of the plurality of samples;

forming a feature vector using the time and frequency domain characteristic parameters of each sample, and forming a knowledge base from feature vectors of all samples;

training a classifier by using the feature vectors of the knowledge base; and

assessing the main insulation condition by using the trained classifier.

In a preferred embodiment of the method, the accelerated thermal aging tests includes steps of: performing the accelerated thermal aging test on the sample for a specific period, and then exposing the sample in air for moisture absorption, so as to prepare a sample with the standard state.

In a preferred embodiment of the method, the extracting time and frequency domain characteristic parameters of each of the plurality of samples further includes:

obtaining frequency domain spectroscopy of each sample, and then extracting a plurality of frequency domain characteristics parameters of the each sample;

measuring time domain spectroscopy of the sample, calculating return voltage curve of the sample, and extracting a plurality of time domain characteristics parameters according to the time domain spectroscopy and the return voltage curve.

In a preferred embodiment of the method, the time domain spectroscopy is calculated by measurement of an analyzer, or by inverse Fourier transform of the frequency domain spectroscopy.

In a preferred embodiment of the method, the return voltage curve is calculated by circuit parameters of extended Debye model.

In a preferred embodiment of the method, input of the classifier comprises feature vectors formed by the plurality of frequency and time domain characteristic parameters, and output of the classifier comprises the standard states.

In a preferred embodiment of the method, the assessing the main insulation condition includes steps of:

measuring frequency domain spectroscopy of entire main insulation and conductivity of oil;

calculating equivalent frequency domain spectroscopy of oil-immersed pressboard using geometric parameters of main insulation;

based on the knowledge base, transforming the equivalent frequency domain spectroscopy under test temperature to the equivalent frequency domain spectroscopy under reference temperature, and then extracting dielectric characteristics;

constructing state feature vector using the dielectric characteristics;

putting the state feature vector into the classifier to estimate moisture and aging state of the main insulation of the transformer.

In a preferred embodiment of the method, the main insulation is complex oil-paper insulation between adjacent windings in the transformer.

In a preferred embodiment of the method, the oil conductivity of the oil is DC conductivity of the oil at the top of transformer.

In a preferred embodiment of the method, the geometric parameters of main insulation comprise: number of sector component of the main insulation, total thickness of the main insulation barrier, width of spacer between the barriers, distance between medium/low voltage winding and core center, distance between medium/high voltage winding and core center, and height of high, medium and low voltage windings.

It should be understood that above general descriptions and underlining specific descriptions are exemplifying and illustrative, and intend to provide further explanations for the invention defined by the claims.

### BRIEF DESCRIPTION OF THE DRAWINGS

Figures are provided for further understanding of the invention, which is included and formed as a part of the present application. Figures illustrate embodiments of the invention, which are used for explain principles of the invention along with specification of the application. In the figures:

FIG. 1 is a flowchart illustrating basic steps of an intelligent assessment method in according with the invention.

FIG. 2 illustrates an embodiment of process for extracting dielectric characteristics of each sample.

FIG. 3 illustrates an embodiment of process for establishing knowledge base and training classifier.

FIG. 4 illustrates an embodiment of process for condition assessment for transformer main insulation.

FIG. 5 illustrates an embodiment of extended Debye circuit model of oil-paper insulation.

FIG. 6 illustrates structure of main insulation of transformer.

### DETAILED DESCRIPTION

The present invention intends to provide an intelligent assessment method of moisture and aging states of oil-immersed power transformer based on time and frequency domain dielectric characteristics. The method considers the combined influence of test temperature, main insulation structure, oil conductivity and so on, so that it is widely applicable to various oil-immersed power transformers with different main insulation structures. The invention makes up for the deficiency of traditional chemical and electrical methods. It can not only diagnose the moisture penetration, but also assess the aging state of the transformer main insulation which is adaptable to onsite test with the advantage of non-destructiveness, easy to operate, portability, and so on.

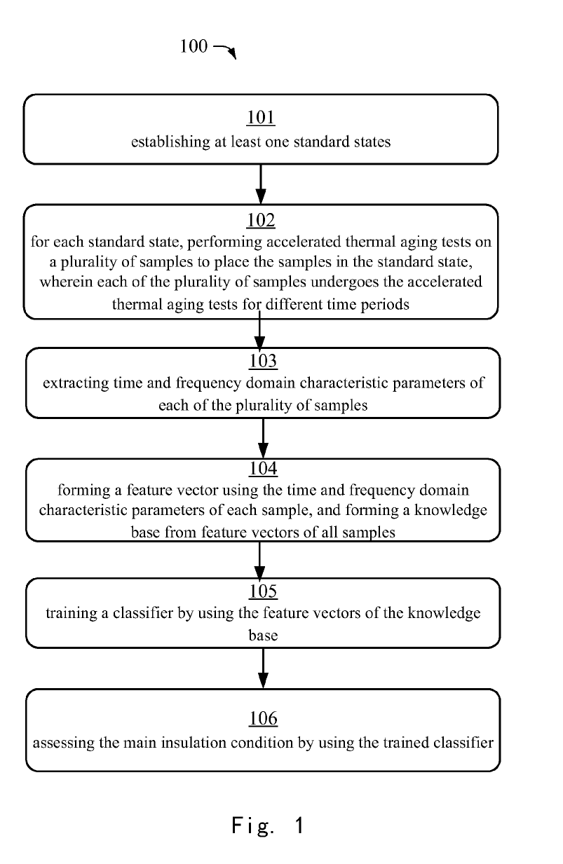

The intelligent assessment method of the invention mainly includes three aspects, i.e., extraction of characteristics, establishment of knowledge base and training process of classifier, and condition assessment for power transformer main insulation. FIGS. 1-4 illustrate embodiments of the intelligent assessment method of the invention, which are discussed in detail in combination with these drawings.

In particular, FIG. 1 is a flowchart illustrating basic steps of an intelligent assessment method in according with the invention. As shown by this figure, an intelligent assessment method 100 of main insulation condition of transformer oil paper insulation comprises:

Step 101: establishing at least one standard states;

Step 102: for each standard state, performing accelerated thermal aging tests on a plurality of samples to place the samples in the standard state, wherein each of the plurality of samples undergoes the accelerated thermal aging tests for different time periods;

Step 103: extracting time and frequency domain characteristic parameters of each of the plurality of samples;

Step 104: forming a feature vector using the time and frequency domain characteristic parameters of each sample, and forming a knowledge base from feature vectors of all samples;

Step 105: training a classifier by using the feature vectors of the knowledge base; and

Step 106: assessing the main insulation condition by using the trained classifier.

Hereinafter the invention is discussed by specific embodiments. Of course, the invention is not limited in the following discussed embodiments. The invention can be properly changed and adjusted within scope defined by the claims.

According to one preferred embodiment, at least one standard states (denoted with 3 in FIG. 3), e.g., N kinds of standard states of oil-paper insulation samples of transformer are established by for example analyzing typical aging state and moisture content of transformer oil-paper insulation during operation, Step 101.

For each standard state, accelerated thermal aging tests are performed for a specific period on a plurality of samples (e.g., M samples, and thus N×M oil-paper insulation samples in total), and then the samples will be exposed in ambient air to absorb moisture content in order to place the samples in its standard state, Step 102. For example, the samples may be placed on electronic scales to absorb moisture content from ambient air to place the samples in its standard state. Further, it is preferable to make sure that the number of samples with each standard state is M.

In Step 103, time and frequency domain characteristic parameters of each of the plurality of samples are extracted ((denoted with 4 in FIG. 3). In a preferred embodiment, after frequency domain spectroscopy of each sample, a plurality of frequency domain characteristics parameters of the each sample are extracted. Time domain spectroscopy of the sample is measured, and then return voltage curve of the sample is calculated. A plurality of time domain characteristics parameters are extracted according to the time domain spectroscopy and the return voltage curve.

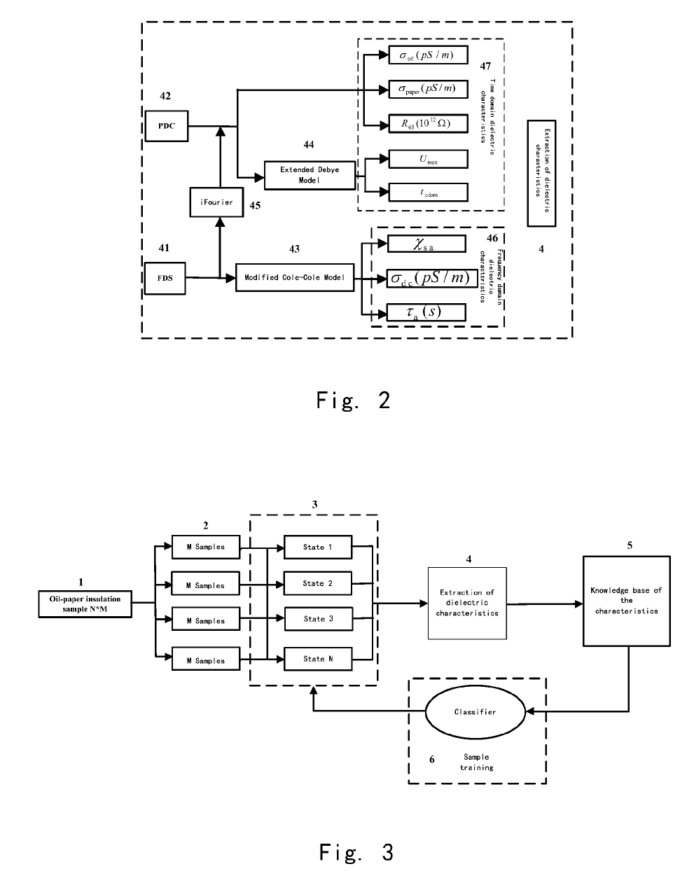

By way of example, turn to FIG. 2, the Step 103 can especially include the following steps:

measuring frequency domain spectroscopy (FDS) of each sample (denoted with 41 in FIG. 2), and then utilizing modified Cole-Cole model to extract three frequency domain characteristic parameters of each sample; and

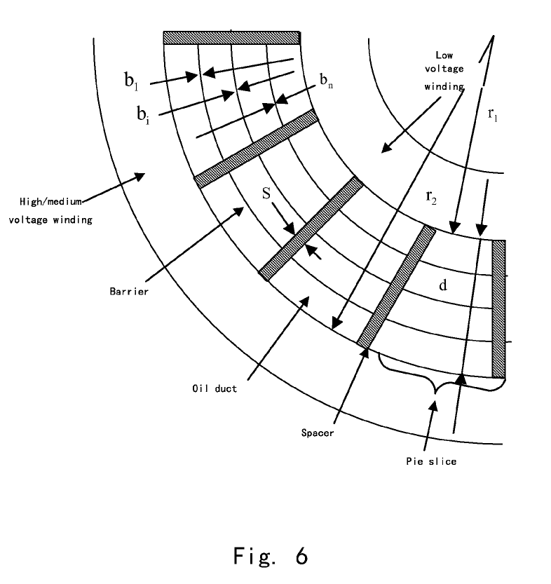

in order to obtain the time domain dielectric spectroscopy PDC (denoted with 42 in FIG. 2) of each sample, establishing extended Debye model of oil-paper insulation sample (denoted with 44 in FIG. 2), and calculating return voltage curve (RVM) based on the circuit parameters of extended Debye model, then extracting five time domain characteristic parameter (denoted with 47 in FIG. 2) according to the PDC and RVM curve, wherein two methods can be used to obtain the PDC, one of which is to measure the PDC curves by an analyzer, and the other is to calculate the PDC curves by inverse Fourier transform of frequency domain dielectric spectroscopy (denoted with 45 in FIG. 2). The extended Debye circuit model is shown in FIG. 5, in which R0 and C0 are insulation resistance and geometric capacitance, respectively, τi is time constant of series-parallel branches (τi=Ri*Ci) that are used to simulate polarization phenomenon under different relaxation time.

As illustrated by FIG. 3, in Step 104, a feature vector is formed using the time and frequency domain characteristic parameters of each sample, e.g., time-frequency domain characteristic parameters (denoted with 47 and 48 in FIG. 2) of each oil-paper insulation sample are grouped into a feature vector, and then the feature vectors of all the samples can form a knowledge base (denoted with 5 in FIG. 3), such as a dielectric fingerprint knowledge base.

In Step 105, a classifier is trained by using the feature vectors of the knowledge base (denoted with 6 in FIG. 3). The classifier can choose a BP neural network, support vector machine, and so on. In particular, in this embodiment, input parameters of the classifier might be a plurality of time domain characteristic parameters and a plurality of frequency domain characteristic parameters (in the above example, there are eight time-frequency domain characteristic parameters in total), while output parameters thereof might be the above-mentioned standard states. In this case, the knowledge base can be used to train and solve the classifier.

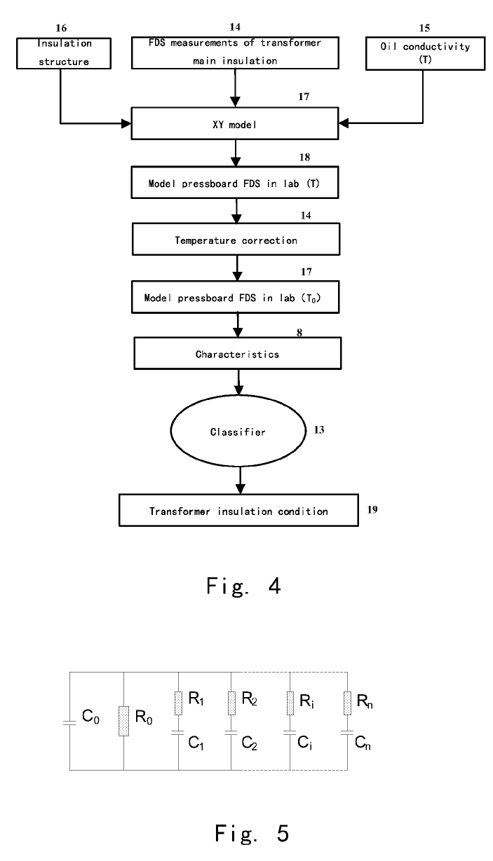

Finally, in Step 106, the trained classifier is used to assess the main insulation condition of the transformer. Preferably, in accordance with FIG. 4, the Step 106 can further include the following steps.

For an oil-immersed power transformers with unknown insulation condition, oil conductivity σ and complex capacitance spectrum C*(ω) of the main insulation are measured at first, in which the main insulation is preferred to be oil-paper insulation between adjacent winding in the transformer, as shown in FIG. 6, and the oil conductivity is preferred to be DC conductivity σ(T) of oil at the top of transformer.

Geometric parameters of the main insulation are collected, which are then utilized to calculate equivalent frequency domain spectroscopy of oil-immersed pressboard. For example, the geometric parameters of main insulation can include, but not limited to, number of sector component of the main insulation n, total thickness of main insulation barrier

$$B = {\sum }_{n = 1}^{n} {b}_{n} ,$$

width of spacer between the barriers, distance between medium/low voltage winding and core center r1, distance between medium/high voltage winding and core center r2, and height of high, medium and low voltage windings h.

Based on the knowledge base, the equivalent frequency domain spectroscopy under test temperature is transformed to the equivalent frequency domain spectroscopy under reference temperature, and then dielectric characteristics are extracted.

State feature vector is constructed using the dielectric characteristics.

The state feature vector is put into the classifier to estimate moisture and aging state of the main insulation of the transformer

Moreover, the complex permittivity 11 of transformer pressboard at field test temperature can be figured out by XY model. In this instance, the frequency domain spectroscopy 11 at test temperature T is shifted to that at the specified temperature T0, at which the knowledge base is established in the laboratory. To extract time-frequency domain characteristic parameters 4, it should be noticed that the time-domain dielectric spectroscopy 42 of transformer pressboard is obtained by the inverse Fourier transform 45 of its frequency domain spectroscopy 41. The time-frequency domain characteristic parameters of transformer pressboard are grouped into a feature vector, which are fed into the trained classifier 6 and the aging state and moisture of transformer insulation will be determined.

In summary, the intelligent assessment method of the invention considers insulation geometry, temperature and oil of transformer, and thus is suitable for field assessment of different voltage grades of oil-immersed transformer insulation condition. The method adopts feature vector consisting of time-frequency domain characteristic parameters rather than a single characteristic parameter. Additionally, the invention introduces intelligence pattern recognition to reflect typical aging state and moisture content of transformer oil-paper insulation during operation, which is more scientific and accurate.

Compared with traditional technique, the method of the invention can not only assess moisture content of transformer, but also provide information regarding aging states. The assessment accuracy will be constantly improved as the knowledge base keeps expanding by adding new samples into it.

As can be seen by one person skilled in the art, the above embodiments of the invention can be varied or modified without departure of spirit and scope of the invention. Thus, the invention covers any variation and modification that is within the scope defined by the claims and its equivalent solutions.

What is claimed is:

1. An intelligent assessment method of main insulation condition of transformer oil paper insulation, comprising:
establishing at least one standard states;
for each standard state, performing accelerated thermal aging tests on a plurality of samples to place the samples in the standard state, wherein each of the plurality of samples undergoes the accelerated thermal aging tests for different time periods;
extracting time and frequency domain characteristic parameters of each of the plurality of samples;
forming a feature vector using the time and frequency domain characteristic parameters of each sample, and forming a knowledge base from feature vectors of all samples;
training a classifier by using the feature vectors of the knowledge base; and
assessing the main insulation condition by using the trained classifier.

2. The method of claim 1, wherein the accelerated thermal aging tests includes steps of:
performing the accelerated thermal aging test on the sample for a specific period, and then exposing the sample in air for moisture absorption, so as to prepare a sample with the standard state.

3. The method of claim 1, wherein the extracting time and frequency domain characteristic parameters of each of the plurality of samples further includes:
obtaining frequency domain spectroscopy of each sample, and then extracting a plurality of frequency domain characteristics parameters of the each sample;
measuring time domain spectroscopy of the sample, calculating return voltage curve of the sample, and extracting a plurality of time domain characteristics parameters according to the time domain spectroscopy and the return voltage curve.

4. The method of claim 3, wherein the time domain spectroscopy is calculated by measurement of an analyzer, or by inverse Fourier transform of the frequency domain spectroscopy.

5. The method of claim 3, wherein the return voltage curve is calculated by circuit parameters of extended Debye model.

6. The method of claim 3, wherein input of the classifier comprises feature vectors formed by the plurality of frequency and time domain characteristic parameters, and output of the classifier comprises the standard states.

7. The method of claim 1, wherein the assessing the main insulation condition includes steps of:
measuring frequency domain spectroscopy of entire main insulation and conductivity of oil;
calculating equivalent frequency domain spectroscopy of oil-immersed pressboard using geometric parameters of main insulation
based on the knowledge base, transforming the equivalent frequency domain spectroscopy under test temperature to the equivalent frequency domain spectroscopy under reference temperature, and then extracting dielectric characteristics;
constructing state feature vector using the dielectric characteristics;
putting the state feature vector into the classifier to estimate moisture and aging state of the main insulation of the transformer.

8. The method of claim 7, wherein the main insulation is complex oil-paper insulation between adjacent windings in the transformer.

9. The method of claim 7, wherein the oil conductivity of the oil is DC conductivity of the oil at the top of transformer.

10. The method of claim 7, wherein the geometric parameters of main insulation comprise: number of sector component of the main insulation, total thickness of the main insulation barrier, width of spacer between the barriers, distance between medium/low voltage winding and core center, distance between medium/high voltage winding and core center, and height of high, medium and low voltage windings.
